(19) United States
(12) Patent Application Publication
(10) Pub. No.: US 2025/0285861 A1
(43) Pub. Date: Sep. 11, 2025

(54) WAFER-SCALE LAYERED TWO-DIMENSIONAL MATERIAL TRANSFER METHOD

(71) Applicant: National Central University, Taoyuan City (TW)

(72) Inventors: Ching-Yuan Su, Taoyuan City (TW); YU-HAN HUNG, Taoyuan City (TW); WAN CHUI Lu, Taoyuan City (TW); Bo-Hao Chen, Taoyuan City (TW)

(21) Appl. No.: 18/671,208

(22) Filed: May 22, 2024

(30) Foreign Application Priority Data
Mar. 8, 2024 (TW) 113108477

(51) Int. Cl. H01L 21/02; H01L 21/283; H01L 29/06; H01L 29/16; H01L 29/24; H01L 29/417; H01L 29/45; H01L 31/0224; H01L 31/028; H01L 31/032; H01L 31/0352

(52) U.S. Cl. CPC H01L 21/02617; H01L 21/283; H10D 62/124; H10D 64/23; H10F 77/14; H10F 77/20; H01L 21/02527; H01L 21/02568; H10D 62/80; H10D 62/882; H10D 64/62; H10F 77/12; H10F 77/122

(57) ABSTRACT

A wafer-scale layered two-dimensional material transfer method includes following steps of: providing a growth substrate with a layered two-dimensional material thereon; coating an adhesive layer on layered two-dimensional material; cold pressing a support layer to the adhesive layer; removing the growth substrate and transferring to a target substrate; removing the support layer; and removing the adhesive layer to obtain a stack comprising the layered two-dimensional material and the target substrate, wherein the layered two-dimensional material is attached on the target substrate.

### CROSS REFERENCE TO RELATED APPLICATIONS

The present invention claims benefit of Taiwan Application No. 113108477, filed in Taiwan Intellectual Property office on Mar. 8, 2024, the disclosure of which is incorporated by reference herein.

### BACKGROUND OF THE INVENTION

### Field of the Invention

The present invention relates to a wafer-scale layered two-dimensional material transfer method, particularly relates to a wafer-scale layered two-dimensional material vacuum lamination transfer method.

### Description of Related Art

The reliable and high-quality transfer of two-dimensional (2D) materials are crucial for versatile integration and advanced electronics. Most preliminary preparation methods. for layered two-dimensional materials, such as graphene and transition metal dichalcogenides (TMDs) such as molybdenum disulfide (MoS₂) and tungsten disulfide (WS₂), rely on mechanical exfoliation. Although mechanical exfoliation can fabricate high-quality layered materials, it lacks controllable thickness and cannot produce sufficient usable surface area. Therefore, mechanical exfoliation is not suitable for large-scale production purposes. Chemical vapor deposition (CVD) provides excellent controllability over film thickness and uniformity. However, the choice of growth substrate is limited by the high temperature of the CVD process and the specific crystalline substrate. For example, graphene with high crystallization and uniformity can be grown on transition metal substrates such as copper (Cu) and nickel (Ni), transition metal chalcogenides (TMDs) can be synthesized on a single-crystal metals (Au) or non-metal substrates like silicon oxide and sapphire. Growth of the 2D directly on oxidized substrates at a higher temperature (>700° C.) by CVD causes the leakage current issue. Especially in the semiconductor process, the thermal budget becomes crucial for adapting the back-end of line (BEOL) integration.

Currently, the most used transfer method for transferring laminated 2D materials is the wet transfer method transferring 2D materials from the growth substrate to the target substrate. A typical wet transfer method uses polymers such as poly (methyl methacrylate) (PMMA) or rosin as adhesive layers. However, this wet transfer process often leads to defects such as wrinkles, rupture, trapped bubbles on the graphene, or polymer residue, and the scalability is limited. Additionally, the container size limits the transfer area and is incompatible with current semiconductor processes. Furthermore, a significant amount of contaminated waste liquid is generated from the etched metal. Another method of transferring large-area graphene to Si wafers or elastic/flexible substrates is roll-to-roll (R2R) lamination method. However, the heat-sensitive and unavoidable non-uniform stress causes the reliability issue when comprising R2R method. Other methods, such as dry transfer method, can also be used to transfer layered two-dimensional materials to a target substrate, but it may still result in residual metal ions affecting material cleanliness. In addition, in many developed dry transfer methods, typical two-dimensional semiconductor materials grown on sapphire substrates also need to be delaminated from the substrate. The adhesive layer used in this process must have sufficient adhesion, but the transfer process must also avoid physical and chemical processes that could damage the adhesive layer. For example, common rosin can experience instability and degradation during this process.

As described above, there are still lots of challenges in the present transfer process. These challenges directly impact the subsequent performance of the components, such as impurity highly effects on low reliability, low carrier mobility, and switching performance. Especially when aiming to maintain ultra-clean transferring over large areas uniformly, wrinkle structure can lead to the deterioration of electrical conduction. Moreover, transferring 2D materials in the atmospheric environment can introduce impurity particles and unwanted molecules, result in the unwanted trapping of gas/liquid cells at the 2D/substrate interface.

Thus, transferring 2D materials from a growth substrate to a target substrate with high uniformity over large area while keeping the high quality (i.e., high crystalline and lower residue) for the future heterogeneous device integration with BEOL compatible procedure is the most significant challenge in large-scale production and it is also the problem to be improved by the method provided in this invention.

### BRIEF SUMMARY OF THE INVENTION

To improve the transfer method described above, a wafer-scale layered two-dimensional material transfer method in accordance with the present invention is provided. In the wafer-scale layered two-dimensional material transfer method, a readily removable doped-rosin (DR) polymer is used as an adhesive layer to replace traditional polymethyl methacrylate (PMMA) or conventional rosin, thereby residue issues are improved. The doped rosin is stable during the transfer process while retaining mechanical flexibility, thereby substantially suppressing the formation of crack, wrinkle, and other defects. Moreover, the low adsorption energy of DR makes the readily removal of the adhesive layer to improve the residue issues effectively. Additionally, the vacuum lamination (VL) device is employed to achieve controlled compression and minimize the formation of trapped gas cell during the transfer process.

A wafer-scale layered two-dimensional material transfer method provided in this invention includes following steps of: providing a growth substrate with a layered two-dimensional material thereon; coating an adhesive layer on the layered two-dimensional material; cold pressing a support layer to the adhesive layer; removing the growth substrate and transferring to a target substrate; removing the support layer; and removing the adhesive layer to obtain a stack comprising the layered two-dimensional material and the target substrate, wherein the layered two-dimensional material is attached on the target substrate.

Furthermore, the cold pressing is under vacuum.

Furthermore, the support layer is selected from a group consisting of polymethyl methacrylate (PMMA), polyethylene terephthalate (PET), polycarbonate (PC), polypropylene carbonate (PPC), polyimide, thermal release tape, polylactic acid (PLA), pressure-sensitive release tape, water-soluble tape, UV release tape, photoresist, polyethylene, polydimethylsiloxane (PDMS), Ethylene-vinyl acetate copolymer (EVA), wax, and poly(para-xylene).

Furthermore, the support layer is a thermal release tape. The hot pressing is performed to desorb and remove the thermal release tape.

Furthermore, the hot pressing is performed under vacuum.

Furthermore, the support layer is a UV release tape. The UV release tape is removed by UV illumination.

Furthermore, the support layer is a pressure-sensitive release tape. The pressure-sensitive release tape is removed by performing lamination.

Furthermore, the adhesive layer is selected from a group consisting of polymethyl methacrylate (PMMA), rosin, camphor, paraffin wax, polystyrene, menthol, methyl methacrylate, polycarbonate, dicyclopentadiene, and doped rosin.

A layered two-dimensional material optoelectronic device including the stack of layered two-dimensional material/target substrate fabricated by the transfer method mentioned above. The layered two-dimensional material serves as the photoactive material for the photodetection element, or as the contact electrode for electronic conduction, or as a hybrid heterostructure of the above.

A semiconductor device of layered two-dimensional material is provided in present invention including the stack of layered two-dimensional material/target substrate fabricated by the transfer method mentioned above. The layered two-dimensional material serves as the active material for memory, transistors, high-frequency devices, or as the contact electrode for electronic conduction, or as a hybrid heterostructure of the above.

### BRIEF DESCRIPTION OF THE DRAWINGS

FIG. 1 is a flowchart illustrating a transfer method of a wafer-scale layered two-dimensional material of the present invention.

FIG. 2 is a schematic illustration of a wafer-scale layered two-dimensional material transfer method of the present invention.

FIG. 3 ((a) to (c)) shows a comparison of the electrical performance test results of graphene using PMMA and DR as adhesive layers in accordance with a specific embodiment of the present invention.

FIG. 4 is a schematic illustration of a vacuum lamination device in accordance with a specific embodiment of the present invention.

FIG. 5 shows results of sheet resistances of graphene transferred to SiO₂/Si substrate at different pressures for cold pressing in accordance with a specific embodiment of the present invention.

FIG. 6 ((a) to (g)) shows the optical microscopic images of graphene transferred to SiO₂/Si substrate under different hot pressing conditions and the corresponding I_{D}/I_{G}, I_{2D}/I_{G}, and Rₛ in accordance with a specific embodiment of the present invention.

FIG. 7 ((a) to (e)) shows the optical microscopic images of graphene transferred to SiO₂/Si substrate under different hot pressing conditions and the corresponding I_{D}/I_{G}, I_{2D}/I_{G}, and Rₛ in accordance with a specific embodiment of the present invention.

FIG. 8 ((a) to (f)) shows the optical microscopic images of graphene transferred to SiO₂/Si substrate under different hot pressing conditions and the corresponding I_{D}/I_{G}, I_{2D}/I_{G}, and Rₛ in accordance with a specific embodiment of the present invention.

FIG. 9 ((a) to (h)) shows the optical microscopy images and the corresponding material characterization of graphene transferred to SiO₂/Si substrate by using different transfer methods in accordance with a specific embodiment of the present invention.

FIG. 10 ((a) to (l)) shows the optical microscopy images and the corresponding material characterization of MoS₂ transferred to SiO₂/Si substrate by using different transfer methods in accordance with a specific embodiment of the present invention.

FIGS. 11 ((a) and (b)) shows a Raman spectroscopy and Photoluminescence (PL) analysis of MoS₂ transferred to SiO₂/Si substrate by using different transfer methods in accordance with a specific embodiment of the present invention.

FIG. 12 ((a) to (e)) shows the electrical characterizations of MoS₂ transferred to SiO₂/Si substrate transferred to SiO₂/Si substrate by using different transfer methods in accordance with a specific embodiment of the present invention.

### DETAILED DESCRIPTION OF THE INVENTION

Regrading technical solutions of the present invention, several preferred embodiments are exemplified and illustrated in detail below in accompany with drawings so as to provide the public with an in-depth understanding and recognition of the present invention. The following detailed description and accompanying drawings are provided to further explain the methods, means, and effects employed by the present invention to achieve its intended purposes. However, the explanations in the embodiments are merely illustrative of the technical content and intended effects of the invention. The dimensions and proportions in the drawings are for explanatory purposes and not intended to directly limit the scope of the invention.

The present invention is further described in detail below in conjunction with the accompanying drawings so that those with ordinary knowledge in a technical field to which the present invention belongs can implement the present invention with reference to descriptions of the specification of the present invention. If there are descriptions involving “first”, “second”, etc., for preferred embodiments of the present invention, the descriptions of “first”, “second”, etc., are used for descriptive purposes only and cannot be understood as indicating or implying their relative significance, or as implicit indication of a quantity of indicated technical features. Therefore, features defined and depicted as “first” and “second” may be considered explicitly or implicitly that at least one of the features is included.

In descriptions of the present invention, it should further be explained that, unless there are more explicit definitions and limitations, the terms of “disposing” and “connection” should be understood in a much broader sense. For example, “connection” can be a disposing connection, and can also be a dismantlable connection or an integral connection. Besides, “connection” can be a mechanical connection or can also be an electrical connection. Meanwhile, “connection” can be a direct connection or an indirect connection through an intermediate medium, or can be an internal connection between two components. For those with ordinary knowledge in a technical field to which the present invention belongs, specific meanings of the above terms in a disclosure of the present invention can be understood based on actual situations.

In addition, if “and/or” appears in descriptions of the present invention, its meaning includes three juxtaposed solutions. Taking “A and/or B” as an example, its meaning includes a solution of A being solely included, a solution of B being solely included, or a solution of A and B being simultaneously satisfied. In addition, technical solutions in various preferred embodiments of the present invention can be combined with each other, but the combination must be based on a fact that a person with ordinary knowledge in the technical field to which the invention belongs can realize the combination. When the combination of the above technical solutions is contradictory to each of the above technical solutions or cannot be realized, the combination of the above technical solutions should be considered as if the combination does not exist, and should also be not within a protection scope intended for the present invention.

In following descriptions, technical solutions of the present invention are described in detail with reference to the accompanying drawings. Devices described below or operating methods thereof are only used to illustrate the preferred embodiments of the present invention and are not used to define a scope of the present application. Furthermore, the same reference numbers depicted in the specification of the present invention refer to the same components, respectively.

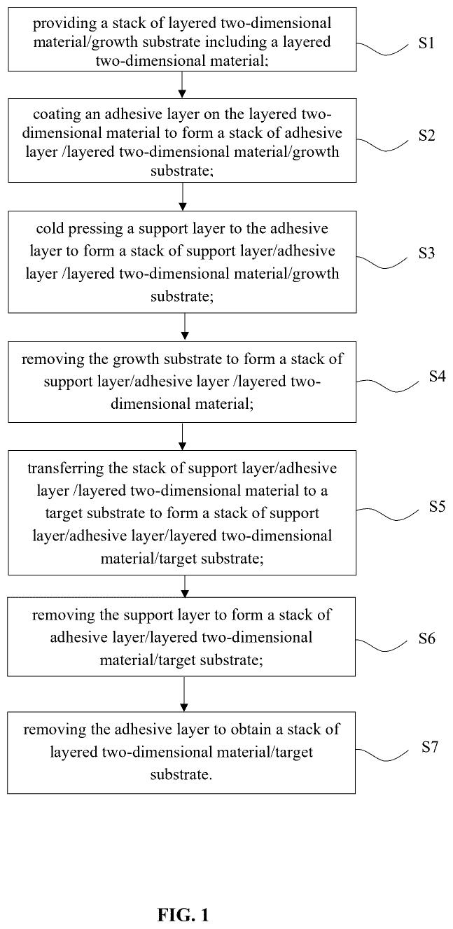

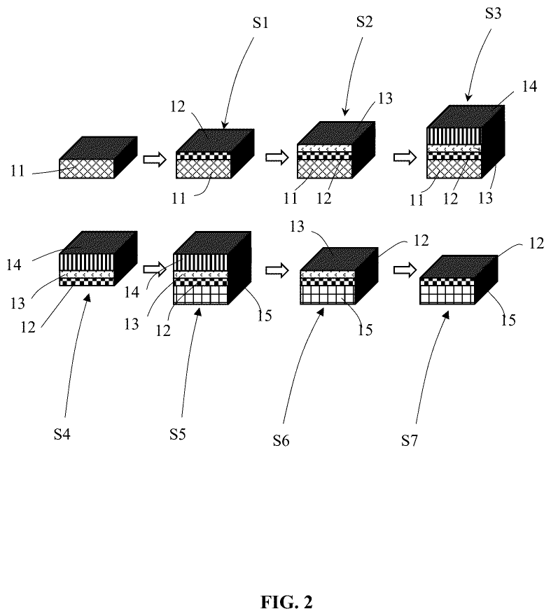

Please refer firstly to FIG. 1 and FIG. 2. FIG. 1 is a flowchart illustrating a transfer method of a wafer-scale layered two-dimensional material of the present invention. FIG. 2 is a schematic illustration of a wafer-scale layered two-dimensional material transfer method of the present invention. A wafer-scale layered two-dimensional material transfer method of present invention includes steps of S1 to S7: S1: providing a stack of layered two-dimensional material/growth substrate including a layered two-dimensional material; S2: coating an adhesive layer 13 on the layered two-dimensional material 12 to form a stack of adhesive layer/layered two-dimensional material/growth substrate; S3: cold pressing a support layer 14 to the adhesive layer 13 under vacuum conditions (about 120 mTorr) to form a stack of support layer/adhesive layer/layered two-dimensional material/growth substrate; S4: removing the growth substrate 11 from the stack of the support layer/adhesive layer/layered two-dimensional material/growth substrate to form a stack of support layer/adhesive layer/layered two-dimensional material; S5: transferring the stack of support layer/adhesive layer/layered two-dimensional material to a target substrate 15 to form a stack of support layer/adhesive layer/layered two-dimensional material/target substrate; S6: removing the support layer 14 from the stack of support layer/adhesive layer/layered two-dimensional material/target substrate to form a stack of adhesive layer/layered two-dimensional material/target substrate; S7: removing the adhesive layer 13 from the stack of adhesive layer/layered two-dimensional material/target substrate to obtain a stack of layered two-dimensional material/target substrate.

The layered two-dimensional material 12 may include, but is not limited to, monolayers, bilayers, and multilayered two-dimensional materials in this disclosed invention. The layered two-dimensional material 12 may include, but is not limited to, graphene, transition metal chalcogenides (TMDs) such as molybdenum disulfide (MoS₂) and tungsten disulfide (WS₂) in this disclosed invention.

In step S1, the growth substrate 12 for synthesizing graphene can be a metal substrate. The metal substrate includes, but are not limited to, copper, nickel, cobalt, and/or any alloy combinations thereof. The methods for synthesizing graphene include, but are not limited to, mechanical exfoliation, method of reduction of graphene oxide, liquid phase exfoliation, epitaxial growth, chemical vapor deposition (CVD), electrochemical exfoliation, and plasma-enhanced chemical vapor deposition (PECVD). In an embodiment of the presently disclosed invention, the monolayer graphene is synthesized using an automated atmospheric-pressure chemical vapor deposition (APCVD) system. Firstly, the copper foil (35 μm thick, 99.8%) is loaded into a horizontally movable tubular quartz furnace and vacuumed to 6×10⁻³ Torr. The temperature is then ramped up to 1060° C. while maintaining a pressure of 760 Torr using a mixed gas of H₂/Ar (20/80 sccm). Subsequently, the copper surface undergoes surface annealing for 30 minutes under a mixed gas of H₂/Ar (20/80 sccm) at 760 Torr, reducing and flattening. During the growth process, the gas flow switched to a mixed CH₄/H₂/Ar gas (1000/30/1 sccm). Finally, the furnace automatically moved out, and the sample was cooled to room temperature naturally under an Ar flow of 80 sccm to complete the synthetization of graphene.

Additionally, the growth substrate can also be a copper film deposited on silicon wafers or sapphire substrates by vapor deposition or sputtering. After deposition of the copper film, the CVD process is performed as mentioned above. In this way, it can facilitate easier integration with wafer fabrication processes of semiconductor industry. Furthermore, deposition of a Cu film on a sapphire substrate can achieve optimal single crystal orientation of Cu, thereby promoting the growth of continuous single-crystal graphene film.

The growth substrate 11 for synthesizing MoS₂ may include, but is not limited to, single-crystal metals (such as Au) or non-metallic substrates (such as silicon dioxide and sapphire). In an embodiment of the presently disclosed invention, high-quality monolayer MoS₂ (CVD-1L-MoS₂) is grown on c-plane (0001) sapphire substrates by chemical vapor deposition in a horizontal hot-wall 3 in. furnace tube with two heating zones. The maximum substrate size can be up to 2 in. wafers. High-purity S (99.5%, Alfa) and MoO₃ (99%, Aldrich) powders are used as the reaction precursors. The S powder is placed in the front heating zone at the upstream side of the furnace, and the temperature is maintained at 140° C. during the reaction. The MoO₃ powder is put into a quartz boat in the center heating zone of the furnace. The temperature of the center heating zone is gradually ramped to 850° C. and held for 10 min. During this process, MoS₂ is grown on the sapphire substrates placed at the downstream side of the MoO₃ quartz boat. All growths are performed in Ar flow gas (90 sccm) at a base pressure of 30 Torr. Finally, the furnace is naturally cooled down to room temperature. The method described above also includes other processes such as MOCVD. The transferred film is not limited to monolayers; it can also be bilayers or multilayers. The transfer process described above can be performed after growing these bilayers or multilayers.

In step S2, an adhesive layer 13 is coated on the surface of the layered two-dimensional material 12. The adhesive layer 13 of the presently disclosed invention may include, but not limited to, polymethyl methacrylate (PMMA), rosin (with abietic acid as the main component), camphor, paraffin wax, polystyrene (PS), menthol, methyl methacrylate (MMA), polypropylene carbonate (PPC), benzocyclobutene (BCB), doped rosin (DR), etc. The clean removal of the polymer of the adhesive layer 13 is still a critical issue and remains challenging, especially when aiming to maintain ultra-clean and ultra-clean transferring over large areas uniformly. The electrical properties of the layered two-dimensional material 12, including sheet resistivity (Rs), carrier mobility, and carrier concentration, are significantly affected by the presence of polymer residue on its surface. In order to improve the residue issue, a doped-rosin (DR) polymer used as an adhesion layer 13 to effectively reduce the residue is disclosed in an embodiment of the present disclosed invention. The doped-rosin (DR) polymer includes abietic acid (C₂₀H₃₂O₂) in replacing traditional polymethyl methacrylate (PMMA) or pristine Rosin. The DR is prepared using a concentrated Rosin solution (Alfa Aesar) as the initial material in the present disclosed invention, followed by a catalytic reaction with a precious metal (Pt/C) of 0.01 wt % under an H₂ atmosphere in a reaction kettle at a temperature of 270° C. for 2 hr. Subsequently, the resulting 48 wt % DR in ethyl lactate was subjected to ultrasonication for 50 minutes. When utilized as an adhesion layer 13 on the layered two-dimensional material 12, the prepared solution is spin-coated on the layered two-dimensional material 12 under the following conditions: 500 rpm for 10 seconds, followed by 1500 rpm for 30 seconds, before being baked at 80° C. to 90° C.

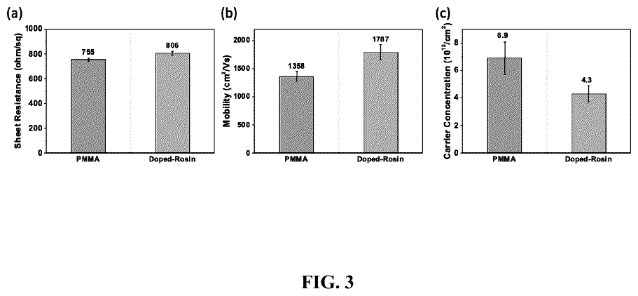

In an embodiment of the present disclosed invention, the effectiveness of using DR as the adhesive layer 13 is verified. Graphene is coated with different adhesive polymers (conventional PMMA and DR disclosed in the present invention) and transferred by R2R transfer method to study the impact of polymer residue and defects on electrical performance of graphene. Please refer to FIG. 3. FIG. 3 shows a comparison of the electrical performance test results of graphene using PMMA and DR as adhesive layers in accordance with a preferred embodiment of the present invention. The average Rs of graphene with PMMA and DR as adhesion layers 13 is around 755 ohm/sq and 800 ohm/sq separately, as shown in FIG. 3(a). The average carrier mobility of graphene transferred using DR (1787 cm²/Vs) is 1.32 times higher than that of graphene transferred using PMMA, as shown in FIG. 3(b). The corresponding carrier concentration of DR (4.3×10¹²/cm²) is certainly lower than PMMA, as shown in FIG. 3(c). According to the verification data above shows a significant affection of surface polymer residue, demonstrating that the graphene films obtained using DR as the adhesive layer 13 exhibit less surface polymer residue than PMMA. Therefore, graphene transferred using DR shows superior average carrier mobility (1787 cm²/Vs). The doped rosin exhibits stable physicochemical properties during the transfer process while retaining mechanical flexibility, thereby substantially suppressing the formation of crack, wrinkle, and other defects. Moreover, the low adsorption energy of DR makes the ease removal of the adhesive layer to improve the residue issue effectively.

The support layer 14 is laminated on the adhesive layer 13 in the present disclosed invention. The support layer 14 may include polymer materials such as, but is not limited to: poly(methyl methacrylate) (PMMA), polyethylene terephthalate (PET), polyimide (PI), thermal release tape (TRT), polycarbonate (PC), polypropylene carbonate (PPC), polylactic acid (PLA), pressure-sensitive release tape, water-soluble tape, UV release tape, photoresist (PR), polyethylene (PE), polydimethylsiloxane (PDMS), polyethylene vinyl acetate (EVA), wax, parylene, and others.

Additionally, when doped rosin (DR) is exposed to the atmosphere, intracyclic peroxides occur. DR become unstable and prone to decomposition. Compared to rosin, DR exhibits higher susceptibility to oxidation and degradation in a humid and oxygen-rich environment. This susceptibility causes DR to completely dissociate and transform into short-chain molecules. Moreover, transferring 2D materials in the atmospheric environment can introduce impurity particles and result in the unwanted trapping of gas/liquid cells at the 2D/substrate interface, which can lead to the deterioration of electronic performance and reliability. Therefore, a vacuum lamination (VL) method under a highly vacuumed condition is disclosed in the present invention. Compared to atmospheric hot pressing or R2R methods, this controlled flat pressing design in a vacuum environment minimizes trapped contamination and gas cell during transfer, reducing transfer-induced defects significantly and ensuring the fabrication of wafer-scale 2D film with high quality. The present invention discloses cold pressing of the support layer/adhesive layer/layered two-dimensional material/growth substrate stack mentioned above under vacuum.

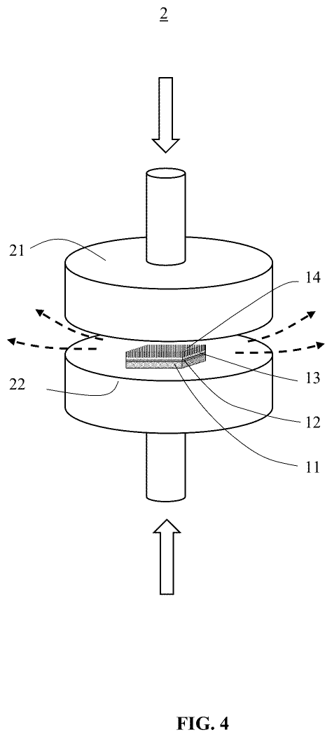

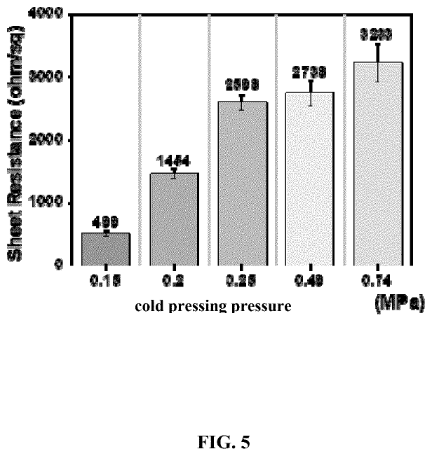

In step S3, a vacuum lamination device 2 is provided in the present disclosed invention. The vacuum lamination device 2 may provide a vacuum environment for cold pressing the support layer/adhesive layer/layered two-dimensional material/growth substrate stack. Please refer to FIG. 4. FIG. 4 is a schematic illustration of a vacuum lamination device 2 in accordance with a specific embodiment of the present invention. The vacuum lamination device 2 includes a top stage 21 and a bottom stage 22 providing the homogeneous distribution of lamination pressure. When the pressure is applied by the top stage 21 and the bottom stage 22 to the support layer/adhesive layer/layered two-dimensional material/growth substrate stack, the space between the top part 21 and the bottom part 22 can also maintain a vacuum environment. The vertical arrow indicates the direction of pressure application, while the dashed arrow represents vacuum evacuation, as shown in FIG. 4. The homogeneous distribution of lamination pressure within the top stage 21 and bottom stage 22 is critical for fabricating high-quality wafer-scale layered two-dimensional materials. The lamination pressure can be monitored in real time by thin-film pressure sensors. FIG. 5 shows sheet resistances of graphene transferred to SiO₂/Si substrate at different pressures for cold pressing in accordance with an embodiment of the present invention. FIG. 5 shows the results of different pressures for cold pressing on Rs using Hall effect measurements. The Rs values are 499, 1454, 2598, 2738, and 3233 ohm/sq for cold pressing pressures of 0.15, 0.2, 0.25, 0.49, and 0.74 MPa, respectively. It shows that increasing of the cold pressing pressure during the lamination process significantly increases Rs (sheet resistance), indicating that higher cold pressing pressure may potentially damage the graphene film.

Step S4 includes removing the growth substrate 11 of the support layer/adhesive layer/layered two-dimensional material/growth substrate stack, forming a support layer/adhesive layer/layered two-dimensional material stack. In an embodiment of the present disclosed invention, the layered two-dimensional material 12 is graphene, and the growth substrate 11 is a copper substrate. The support layer/adhesive layer/layered two-dimensional material/growth substrate stack is immersed in a 0.5M FeCl₃ solution to etch the copper substrate and placed in deionized water to dilute residue. In another embodiment of the present disclose invention, the layered two-dimensional material 12 is MoS₂, and the growth substrate 11 is a sapphire substrate. The support layer/adhesive layer/layered two-dimensional material/growth stack is immersed in a 0.2M NH₄OH solution for separation.

Step S5 includes transferring the support layer/adhesive layer/layered two-dimensional material stack to a target substrate 15, forming a support layer/adhesive layer/layered two-dimensional material/target substrate stack. The target substrate 15 can include but is not limited to a SiO₂/Si substrate.

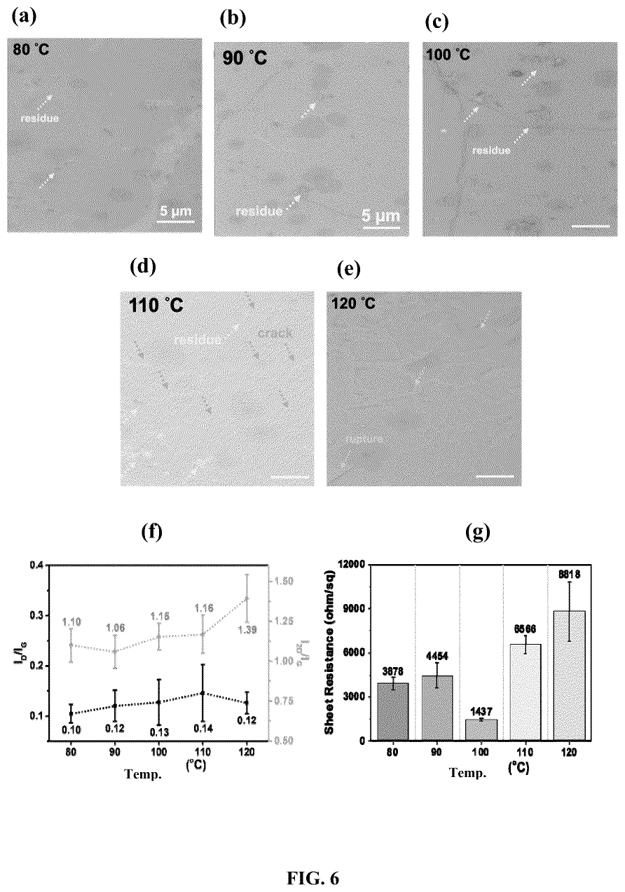

The support layer/adhesive layer/layered two-dimensional material/target substrate stack can be dried at 80° C. for 10 minutes, followed by the Step S6 to remove the support layer 14. In an embodiment of the present disclosed invention, the support layer 14 is a thermal release tape. Hot pressing the support layer/adhesive layer/layered two-dimensional material stack is performed to remove the support layer 14 under a vacuum environment provided by the vacuum lamination device 2. The as-prepared samples are hot-pressed using the vacuum lamination device 2 at optimized temperature, pressure, and time. The hot-pressing conditions of the present disclosed invention include parameters such as temperature, time, and pressure. Please refer to FIG. 6. FIG. 6 shows the optical microscopic images of graphene transferred to SiO2/Si substrate under different hot pressing conditions and the corresponding ID/IG, I2D/IG, and Rs in accordance with an embodiment of the present invention. FIG. 6(a) to FIG. 6(e) show the surface morphologies of graphene at different temperatures of 80° C., 90° C., 100° C., 110° C., and 120° C. for hot pressing. Surface morphologies of graphene served as layered 2D material 12 reveal cracks and ruptures at 80° C., 90° C., 110° C., and 120° C. At 110° C. and 120° C., cracks and fractures indicate rapid detachment of the support layer and slight melting of DR, resulting in unbalanced attachment of the adhesive layer/layered two-dimensional material stack on the target substrate 15. Similarly, at 80° C. and 90° C., insufficient releasing of support layer, uneven peel-off, and polymer residue, cause incomplete attachment of the adhesive layer/graphene structure on the target substrate 15. While at 100° C., only polymer residue remained, and a crack-free graphene film is obtained. As shown in FIG. 6(f), the I_{D}/I_{G} values at 80° C., 90° C., 100° C., 110° C., and 120° C. are 0.1, 0.12, 0.13, 0.14, and 0.12, respectively. Although their ID/IG values are similar, the corresponding Rs values are 3787, 4454, 1437, 6566, and 8818 ohm/sq. As shown in FIGS. 6(f) and 6(g), the optimized heating conditions (i.e., 100° C.) exhibit the lowest Rs due to good transmission integrity. These results are consistent with the analysis in transferring morphology shown in FIGS. 6(a) to 6(e).

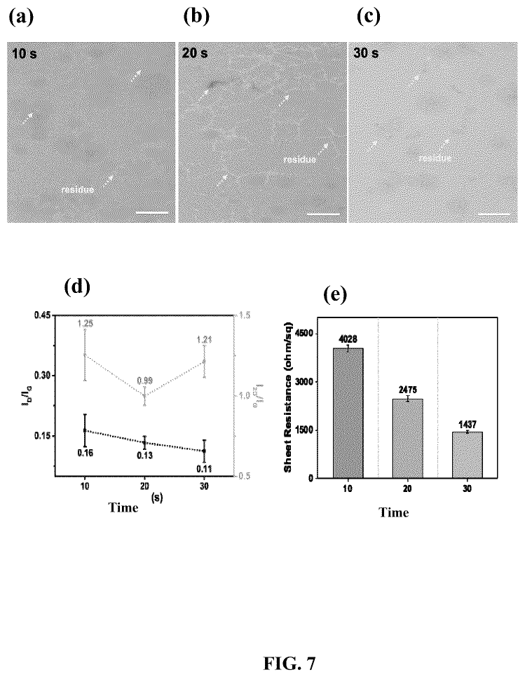

Next, different times of 10 s, 20 s, and 30 s for hot pressing are applied to further ensure the quality of the graphene film. Please refer to FIG. 7. FIG. 7 shows the optical microscopic images of graphene transferred to SiO₂/Si substrate under different hot pressing conditions and the corresponding I_{D}/I_{G}, I_{2D}/I_{G}, and Rs in accordance with a specific embodiment of the present invention. FIG. 7(a) to FIG. 7(c) show the surface morphologies of graphene at different times at 100° C. for hot pressing. Surface morphologies reveal residual DR coverage and cracks at pressing time of 10 s, and the specific grain boundary-shaped residues at 20 s, while fewer residues and lower defect density at 30 s. As shown in FIG. 7(d) to FIG. 7(e), the corresponding I_{D}/I_{G} values are 0.16, 0.13, and 0.11, and the sheet resistance values are 4028 ohm/sq, 2475 ohm/sq, and 1437 ohm/sq, respectively. These results indicate that a hot-pressing lamination time of at least 30 s is necessary to reduce DR residue on the graphene film at a specific temperature (100° C.).

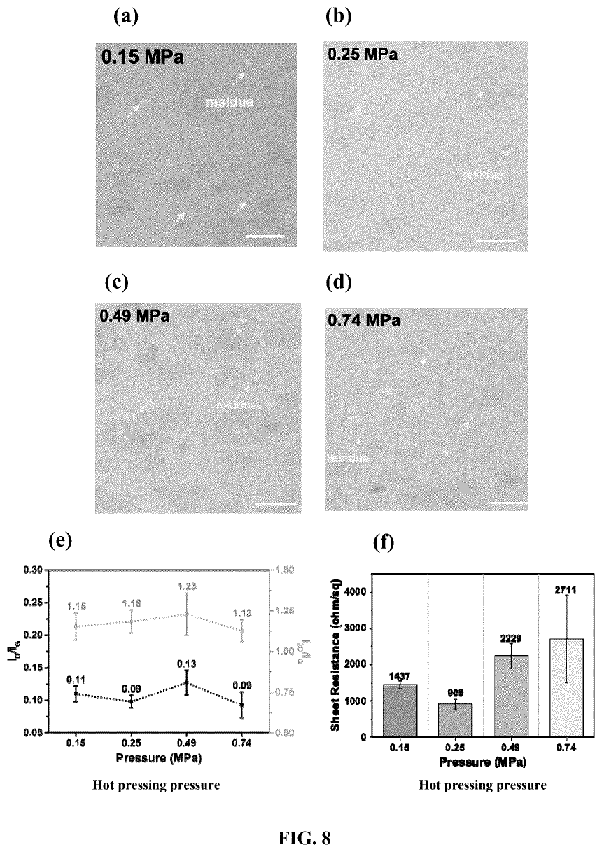

Finally, the effect of hot-pressing pressure during lamination is investigated, from which four hot-pressing pressure conditions of 0.15 MPa, 0.25 MPa, 0.49 MPa, and 0.74 MPa are employed. Please refer to FIG. 8. FIG. 8 shows the optical microscopic images of graphene transferred to SiO₂/Si substrate under different hot pressing conditions and the corresponding I_{D}/I_{G}, I_{2D}/I_{G}, and Rs in accordance with an embodiment of the present invention. FIG. 8(a) to FIG. 8(e) show the surface morphologies of graphene, clearly revealing the distinct presence of DR residue at pressures of 0.15 MPa, 0.49 MPa, and 0.74 MPa. It's worth noting that excessive pressure, particularly at 0.74 MPa, considerably hindered the removal of polymer residue during subsequent processes and easily led to the formation of cracks in the graphene film. However, lower pressing pressure, 0.15 MPa resulted in insufficient bonding adhesion between the DR/graphene and the SiO₂ substrate, potentially impeding the successful transfer of the graphene film. The average I_{D}/I_{G} values at 0.15 MPa, 0.25 MPa, 0.49 MPa, and 0.74 MPa were 0.11, 0.09, 0.13, and 0.09, respectively, as shown in FIG. 8(e) to FIG. 8(f). Although the I_{D}/I_{G} values of 0.25 MPa and 0.74 MPa are similar, the Rs values threefold difference, with values of 909 ohm/sq and 2711 ohm/sq, respectively. These results suggest that excessive hot-pressing pressure (>0.25 MPa) leads to difficulties in removing polymer residue, resulting in increased sheet resistance. Based on the above discussion, the optimized condition for hot-pressing lamination for graphene is: 30 s for hot-pressing time, 100° C. for temperature, and 0.25 MPa for pressure. Under these optimized parameters, graphene films with desirable electrical properties and low defects can be achieved.

In another embodiment of the present disclosed invention, the support layer 14 may be a pressure-sensitive release tape or a UV release tape. Pressure-sensitive release tape relies on applying a fixed pressure to cause the tape to lose adhesion and detach. The UV release tape can be removed after exposure to ultraviolet light. However, under atmospheric pressure, there are inevitable issues such as partial residue during detachment of these polymers, or uneven application of pressure to the film, which can easily lead to defects in the layered two-dimensional material. Therefore, challenges persist in achieving uniform detachment of the support layer 14 under atmospheric pressure. The effective detachment of the support layer 14 can be achieved by using the vacuum lamination method disclosed in the present invention.

In step S7, finally, the adhesive layer/layered two-dimensional material/target substrate stack is immersed in acetone for 15 minutes to remove the adhesive layer, then rinse with IPA (isopropyl alcohol) and DI (deionized) water.

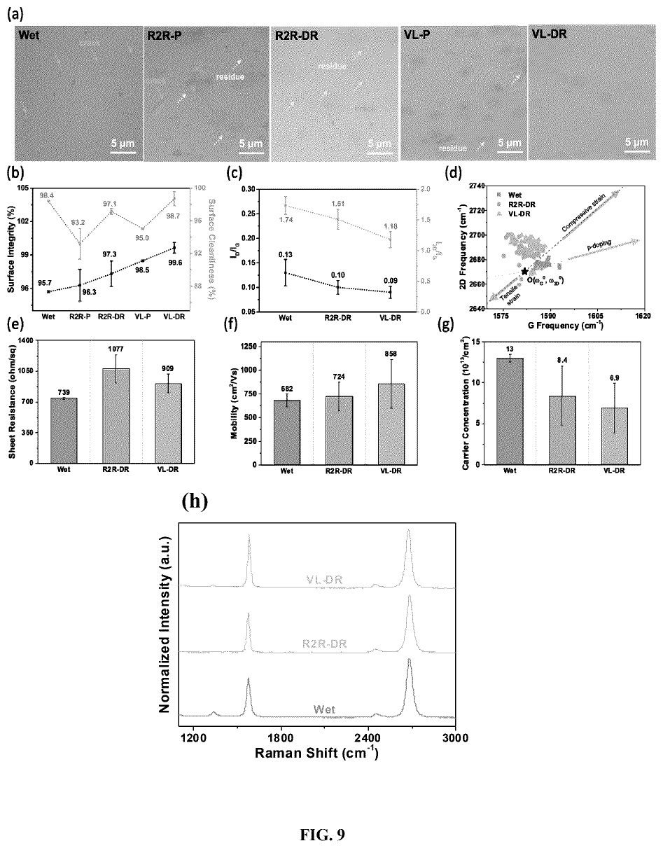

In an embodiment of the present invention, the superior performance of graphene achieved through the optimized vacuum lamination (VL) transferring process disclosed in the invention is evaluated. A comparison of surface integrity, cleanliness, electrical properties, and Raman characterizations of graphene transferred to SiO₂/Si substrate by the conventional wet transfer and roll-to-roll (R2R) methods are conducted. For the R2R, VL, and wet transfer methods, the PMMA and DR are selected as the adhesion layers 14. However, in the case of the wet transfer method, DR serve as the sole adhesion layer 13, which poses a risk as it can easily dissolve in solvents, potentially causing damage to the graphene. Hence, in the experiment, an PMMA coating is applied as the adhesion layer 13 for the wet transfer method. The samples are abbreviated as Wet, R2R-P, R2R-DR, VL-P, and VL-DR, respectively. Please refer to FIG. 9. FIG. 9 shows the optical microscopy images and the corresponding material characterization of graphene transferred to SiO₂/Si substrate by using different transfer methods in accordance with a specific embodiment of the present invention. FIG. 9(a) illustrates that graphene transferred using the wet transfer method exhibits numerous cracks but less polymer residue, resulting in a surface integrity of 95.7% (FIG. 9(b)). In contrast, R2R-P and R2R-DR display minimal polymer residue and cracks on their surfaces. However, R2R-DR demonstrates a more uniform surface cleanliness at 97.1%, which is 3.9% higher than R2R-P, and a surface integrity of 97.3%, which is 1% higher. This result suggests that DR can retain less residue compared to PMMA. Furthermore, VL-P shows a small area of remaining residue on the graphene surface, accompanied by noticeable cracks. Conversely, VL-DR achieves a residue-free and complete surface, exhibiting a high surface cleanliness of 98.7% and surface integrity of 99.6%. Comparing different transfer methods, graphene transferred with DR demonstrates best surface cleanliness and integrity. Additionally, when employing R2R and VL methods, using TRT as the supporting layer 14 becomes necessary to protect the graphene film from stress-induced cracks during the transfer process. Therefore, for further analysis of the obtained quality of transferred films in terms of their electrical properties and defect density, we have selected the wet transfer, R2R-DR, and VL-DR methods for subsequent discussion and comparison. In FIG. 9(h), the Raman spectrum of the wet transfer method reveals a pronounced intensity of the D-band compared to R2R-DR and VL-DR, indicating numerous defects in the transferred graphene through the wet transfer method. This observation aligns with the presence of numerous cracks and ruptures, as shown in FIG. 9(a). To further understanding the quality of graphene films obtained through various transfer methods, the correlation between the G and 2D peaks in the Raman spectrum is analyzed, as shown in FIG. 9(c). the red or blue shifts of the G peak and 2D peak in the Raman spectrum can indicate whether graphene is influenced by doping or strain. We can introduce a correlation graph of ω_{G} and ω_{2D} to determine whether graphene is affected by strain during the transfer process or doped by residues after transfer. In this plot, we define the original point as representing an ideal suspended graphene unaffected by strain or doping, as shown in FIG. 9(d). If graphene is subjected to strain, it will shift towards the right with a slope of 2.2, indicating compression force. Conversely, under tensile strength, it will move towards the left. On the other hand, if graphene is affected by doping, the slope of the original point will be 0.7. Furthermore, as the hole doping level increases, the feature peak position of graphene will shift toward the right in the diagram. Fifty Raman spectra results are collected from various transferring methods for analysis, as shown in FIG. 9(d). The original point of graphene (ω_{G}⁰, ω_{2D}⁰) at (1582 cm⁻¹, 2670 cm⁻¹), representing undoped graphene theoretically unaffected by tensile strain, corresponds to the G and 2D positions of suspended graphene. Suspended graphene serves as a reference point for evaluating the intrinsic characteristics of graphene, mitigating the influence of charge scattering and substrate impurities. It represents the closest approximation of graphene unaffected by tensile stress and doping. The analysis reveals that R2R-DR and VL-DR exhibit compressive stress compared to the wet transfer method, likely resulting from the down force applied during the two-step pressing process. Furthermore, the increased doping level observed in the wet transfer method can be mainly attributed to atmospheric molecules (oxygen) being absorbed on the surface of the graphene and along the edges of the visible cracks, in conjunction with the slight effects of polymer residue on the surface. Hall measurements are also conducted to compare the electronic properties, including their Rs, carrier mobility, and carrier concentration of graphene films obtained through the three transfer methods, as shown in FIG. 9(a) to FIG. 9(e).

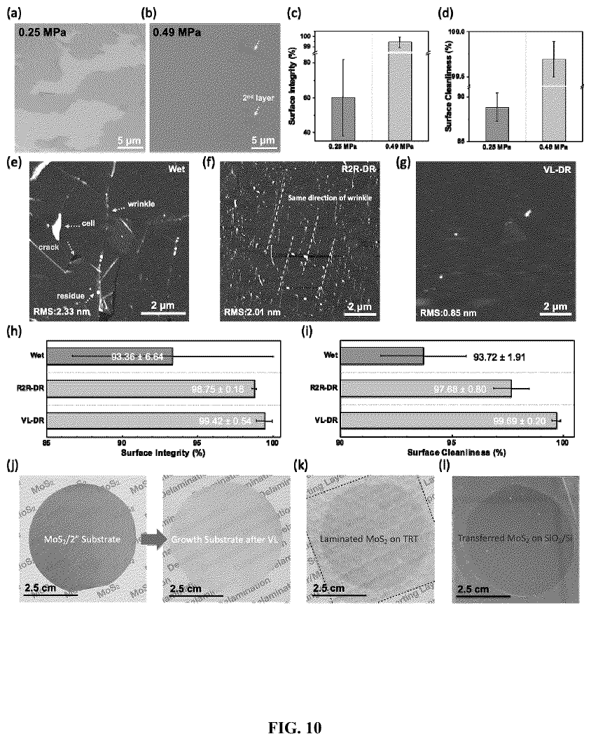

In addition to study on graphene, three transfer methods for transferring MoS₂ are also applied in an embodiment of the disclosed invention. The atomic force microscope (AFM) is employed for morphology characterization with high atomic resolution. To ensure that the quality of the MoS₂ film remains uncompromised under the optimized condition of VL transfer, based on the graphene sample, we observed that MoS₂ could barely detach with the cold pressing pressure of less than 0.25 MPa. Please refer to FIG. 10. FIG. 10 shows the optical microscopy images and the corresponding material characterization of MoS₂ transferred to SiO₂/Si substrate by using different transfer methods in accordance with a specific embodiment of the present invention. FIG. 10(a) shows that using 0.25 MPa resulted in ruptured MoS₂ due to the insufficient cold pressing pressure exerted by the VL, possibly causing incomplete adhesion between the supporting layer and MoS₂. Furthermore, FIG. 10(c) indicates the surface integrity of the MoS₂ at this cold pressing pressure exhibited only 59%. Increasing the pressure to 0.49 MPa resulted in a complete surface and integrity of 99%, as shown in FIG. 10(a) and FIG. 10(c), respectively. Notably, FIG. 10(d) further indicates an exceptionally low deviation in surface integrity (<1.6%) and cleanliness (<0.5%) when utilizing these two cold pressing pressures, indicating the high reliability of the VL transferring method. Based on the optimized VL conditions, the surface morphology of wet transfer, R2R-DR, and VL-DR are shown in FIG. 10(e) to FIG. 10(g). In FIG. 10(e), the MoS₂ transferred through the wet method exhibited extensive wrinkling and numerous cracks and polymer residue due to trapped water residue between MoS₂ and substrate. These unwanted defects resulted in the average surface integrity, surface cleanliness, and root mean square (RMS) of surface roughness measured to be 93.36%, 93.72%, and 2.33 nm, respectively, as shown in FIG. 10(h) and FIG. 10(i). On the other hand, FIG. 10(f) reveals that R2R-DR transferred MoS₂ exhibited the numerous oriented wrinkles on the surface due to the non-uniform linear roller attachment of the TRT supporting layer onto DR/MoS₂. Also, compared to the R2R-DR transferred graphene, as-grown MoS₂ is supported on the rigid sapphire substrate, which can reduce unexpected wrinkles than the softened Cu foil. Therefore, the R2R-DR transferred MoS₂ indicates less wrinkle than the R2R-DR transferred graphene. Although there is a slight reduction in polymer residue due to the DR, the average surface integrity, surface cleanliness, and RMS of surface roughness remained at 98.75%, 97.68%, and 2.01 nm, respectively. As mentioned earlier, DR demonstrates similar advantages in effectively reducing residue on the MoS₂ surface. In contrast, FIG. 10(g) presents a wrinkle-free and minimal residue MoS₂ surface using the VL-DR method. Additionally, transferring MoS₂ from the as-grown obviated the need to etch the entire substrate, resulting in significantly improved average surface integrity, surface cleanliness, and RMS of surface roughness at 99.42%, 99.69%, and 0.85 nm, respectively. This achievement highlights the exceptional cleanliness and flatness attained through the VL-DR transfer process. Moreover, the transferred area of MoS₂ is extended successfully up to 2-inch wafer, as shown in FIG. 10(k). Subsequently, as depicted in FIG. 10(j) and FIG. 10(k), the complete detachment of MoS₂ from the sapphire substrate is observed, and the entire film is successfully transferred onto the TRT as a MoS₂/DR/TRT composite film and or stack. Upon transferring the MoS₂ onto the SiO₂/Si substrate, as presented in FIG. 10(l).

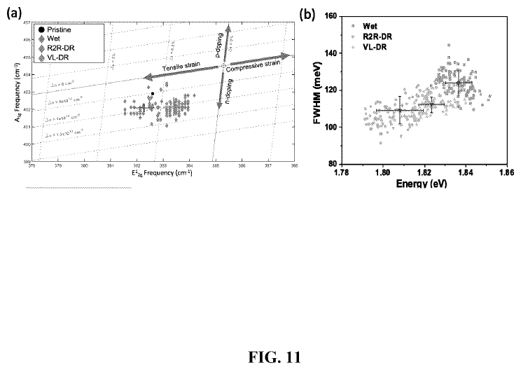

Raman spectroscopy is a valuable tool for studying the effects of strain and doping on MoS₂. Please refer to FIG. 11. FIG. 11 shows a Raman spectroscopy and Photoluminescence (PL) analysis of MoS₂ transferred to SiO₂/Si substrate by using different transfer methods in accordance with a specific embodiment of the present invention. In the case of single-layer MoS₂, as shown in FIG. 11(a), the E¹_{2g} mode corresponds to in-plane vibrations where the Mo and S atoms oscillate in opposite directions. On the other hand, the A_{1g} mode represents out-of-plane vibrations, where only the S atoms move in opposite directions. Specifically, the E¹_{2g} mode is sensitive to strain, while the A_{1g} mode is more sensitive to doping. Thus, the correlation graph of A_{1g} and E¹_{2g} is employed to determine whether MoS₂ is affected by strain during the transfer process or doped by residues after transfer. During the transfer process, the R2R method applies localized downward force and minimal lateral shear force during pressing, resulting in tensile strain on the MoS₂ surface. On the other hand, the VL method offers uniform and evenly distributed downward pressure, leading to compressive strain on the MoS₂. Even in the wet transfer method, which involves scoop-up floating of MoS₂ onto the target substrate, compressive strain can be observed. Photoluminescence (PL) analysis is another technique used to study the electronic structure of materials, providing information about band structure, defects, material structure, and quality, which is widely employed to identify the intrinsic features and transfer quality of MoS₂. MoS₂ exhibits a characteristic change in its energy gap depending on the number of layers. For instance, single-layer MoS₂ has a theoretical energy gap of 1.9 eV, whereas bulk MoS₂ possesses an indirect energy gap of 1.3 eV. However, the peak position and relative intensity of PL also are affected by the strain and doping. Different levels of strain and p-type doping cause a red shift in the PL peak position, while n-type doping results in a blue shift. The PL analysis of MoS₂ transferred to SiO₂ substrate by using the three transfer methods, as shown in FIG. 11(b), indicates that the transferred MoS₂ exhibits peak positions ranging from 1.79 eV to 1.85 eV compared to the as-grown MoS₂ on sapphire, with a red shift range of 10 meV to 80 meV from 1.86 eV. In the case of the R2R method, local pressing has a significant impact on the quality of MoS₂, resulting in an average red shift of approximately 60 meV. Conversely, the VL method, which applies downward pressing uniformly across the MoS₂ surface, leads to a smaller red shift of around 35 meV. In the case of wet transfer, which avoids external force on MoS₂, exhibits an average red shift of nearly 20 meV. Additionally, the average full width at half maximum (FWHM) of the PL peak is approximately 125 meV for wet transfer, while R2R and VL show FWHM values of around 110 meV. It's worth noting that the FWHM indicates similar quality for R2R and VL-transferred MoS₂. However, the reduced data variation in the VL method implies higher homogeneity over a larger area compared to R2R.

In another embodiment of the present disclosed invention, a MoS₂-based FET with a back-gate architecture is fabricated to validate the electronic transport performance of MoS₂ transferred on 100 nm SiO₂/Si using different methods. After transferring MoS₂ onto a silicon substrate with a 300 nm thick oxide layer (SiO₂/Si), the lithography process begins with the spinning coating of hexamethyldisilazane (HMDS) at 3000 rpm for 30 seconds, followed by baking at 110° C. for 1 minute. Subsequently, spin-coated at 1000 rpm for 10 seconds is performed and then at 3000 rpm for 30 seconds. After that, baking is introduced at 110° C. for 5 minutes, resulting in a final thickness of approximately 2.1 μm. Next, oxygen plasma removes the exposed areas and creates the channel. The oxygen plasma is a mixture of Ar gas (80 sccm) and O₂ gas (20 sccm) and is activated at 25 W power for 40 minutes. Subsequently, the source and drain areas are exposed again, and metal electrodes, 3 nm Ti and 30 nm Au are deposited onto the exposed regions using electron beam system CV-6SLX, which is first evacuated to a pressure below 3×10-7 Torr before the electrode deposit. The Al₂O₃ layer is added by ALD. Finally, the lift-off process is carried out to prepare the back-gated field effect transistor. After etching and electrode deposition, the photoresist is removed using acetone and IPA.

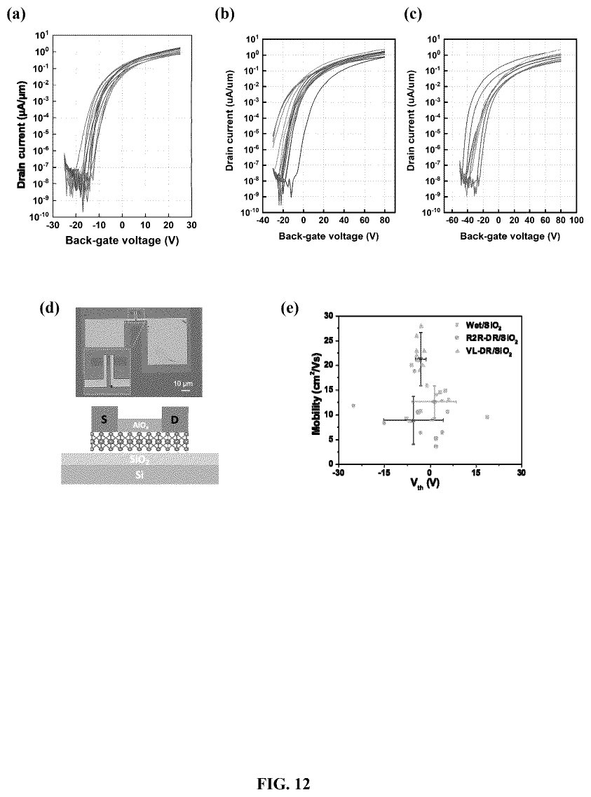

Please refer to FIG. 12. FIG. 12 is a schematic illustration of back-gated field effect transistor fabricated by different transfer methods and their electrical properties in accordance with a specific embodiment of the present invention. In another embodiment of the present disclosed invention, MoS₂-based FETs (as shown in FIG. 12 (a)) are fabricated using three different transfer methods, and their electrical properties are investigated. The drain current and back-gated voltage curves (I_{DS}−V_{GS}) for VL, R2R, and wet transfer methods are shown in FIG. 12 (a) to FIG. 12(c), respectively. The Ion current of these samples ranged from 10⁻¹ to 10⁻² μA/μm. Furthermore, the field effect mobility (μ) is calculated by the formula:

$$μ = \frac{{L}_{ch} \frac{\partial {I}_{d}}{\partial {V}_{g}}}{{W}_{c h} {C}_{o x} {V}_{d}} ,$$

where the L_{ch} and W_{ch} are the length and width of the MoS₂ channel, respectively. Here the L_{ch} and W_{ch} is 5 μm and 10 μm, respectively; V_{d} is 1 V and the Cₒₓ is calculated by the εₒεᵣ/tₒₓ, (εₒ: permittivity of free space, εᵣ: the relative permittivity of the gate dielectric, tₒₓ: the thickness of the gate dielectric) and Vₜₕ collected in FIG. 12(e). From FIG. 12(e), the average field-effect mobility for wet, R2R, and VL transfer methods is determined to be 12.65 cm²/Vs, 8.88 cm²/Vs, and 21.22 cm²/Vs, respectively. The average Vₜₕ values for these methods are 1.28 V, −5.55 V, and −3.11 V, respectively. These results indicate that MoS₂ prepared using the VL transfer method exhibited outstanding performance and uniform quality in terms of both mobility and Vₜₕ.

A layered 2D material/target substrate structure fabricated by the wafer-scale layered 2D material transfer method disclosed in the present invention can be applied to optoelectronic components as a light-responsive active material for photosensitive components, to semiconductor components as an active material for memories, transistors, and high-frequency components, or as contact electrodes for electronic conduction thereof, or as a hybrid heterogeneous structure of the above two types.

In summary, a VL method of utilizing DR as an adhesion layer for transferring layered 2D materials such as graphene and MoS₂ is disclosed in present invention. By optimizing the VL conditions, a residue-free and high integrity of 2D film is achieved over a wafer scale. The transferring quality using the VL transfer approach shows highly improved quality and reliability compared to conventional wet methods and typical R2R transferring methods for 2D materials. Characterizations of electrical properties, surface morphology, Raman spectroscopy, and PL analysis reveal that the transferred MoS₂ through VL-DR exhibits less strain and a large, uniformly high crystallinity area compared to R2R-DR route. Moreover, MoS₂-based FETs fabricated by VL-DR transfer exhibit superior field-effect mobility, measured at about 21.22 cm²/Vs, and can be precise controlled over the threshold voltage at −3.11 V outperforming both wet transfer and R2R-DR methods. These findings underscore the significance of reliable transfer method in achieving wafer-scale, high-quality graphene and MoS₂ films with enhanced electrical properties and surface characteristics. The results contribute to the advancement of 2D material-based devices, highlighting their potential for future applications in electronics.

What is claimed is:

1. A wafer-scale layered two-dimensional material transfer method, comprising steps of:
providing a growth substrate with a layered two-dimensional material thereon;
coating an adhesive layer on the layered two-dimensional material;
cold pressing a support layer to the adhesive layer;
removing the growth substrate and transferring to a target substrate;
removing the support layer; and
removing the adhesive layer to obtain a stack comprising the layered two-dimensional material and the target substrate, wherein the layered two-dimensional material is attached on the target substrate.

2. The wafer-scale layered two-dimensional material transfer method as claimed in claim 1, wherein the cold pressing is under vacuum.

3. The wafer-scale layered two-dimensional material transfer method as claimed in claim 2, wherein the support layer is selected from a group comprising of polymethyl methacrylate (PMMA), polyethylene terephthalate (PET), polycarbonate (PC), polypropylene carbonate (PPC), polyimide, thermal release tape, polylactic acid (PLA), pressure-sensitive release tape, water-soluble tape, UV release tape, photoresist, polyethylene, polydimethylsiloxane (PDMS), Ethylene-vinyl acetate copolymer (EVA), wax, and poly(para-xylene).

4. The wafer-scale layered two-dimensional material transfer method as claimed in claim 3, wherein the support layer is a thermal release tape, and the hot pressing is performed to desorb and remove the thermal release tape.

5. The wafer-scale layered two-dimensional material transfer method as claimed in claim 4, wherein the hot pressing is performed under vacuum.

6. The wafer-scale layered two-dimensional material transfer method as claimed in claim 3, wherein the support layer is a UV release tape, and the UV release tape is removed by UV illumination.

7. The wafer-scale layered two-dimensional material transfer method as claimed in claim 3, wherein the support layer is a pressure-sensitive release tape, and the pressure-sensitive release tape is removed by performing lamination.

8. The wafer-scale layered two-dimensional material transfer method as claimed in claim 1, wherein the adhesive layer is selected from a group comprising of polymethyl methacrylate (PMMA), rosin, camphor, paraffin wax, polystyrene, menthol, methyl methacrylate, polypropylene carbonate, benzocyclobutene, and doped rosin.

9. A layered two-dimensional material optoelectronic device, comprising the stack of layered two-dimensional material/target substrate fabricated by the transfer method as claimed in claim 1, wherein the layered two-dimensional material serves as the photoactive material for the photodetection element, or as the contact electrode for electronic conduction, or as a hybrid heterostructure of the above.

10. A semiconductor device of layered two-dimensional material, comprising the stack of layered two-dimensional material/target substrate fabricated by the transfer method as claimed in claim 1, wherein the layered two-dimensional material serves as the active material for memory, transistors, high-frequency devices, or as the contact electrode for electronic conduction, or as a hybrid heterostructure of the above.
